(19) United States
(12) Patent Application Publication
(10) Pub. No.: US 2012/0104556 A1
(43) Pub. Date: May 3, 2012

(54) POWER DEVICE AND METHOD FOR MANUFACTURING THE SAME

(75) Inventors: Makoto KIYAMA, Osaka-shi (JP); Hiromu SHIOMI, Itami-shi (JP); Kazuhide SUMIYOSHI, Osaka-shi (JP); Akihiro HACHIGO, Itami-shi (JP)

(73) Assignee: SUMITOMO ELECTRIC INDUSTRIES, LTD., Osaka-shi (JP)

(21) Appl. No.: 12/913,538

(22) Filed: Oct. 27, 2010

(51) Int. Cl. H01L 29/20; H01L 21/203

(52) U.S. Cl. 257/615; 438/478; 257/E29.089; 257/E21.099

(57) ABSTRACT

The present power device includes a metal-made support substrate, and a group III nitride conductive layer, a group III nitride active layer and an electrode successively formed on one main surface side of the metal-made support substrate. In addition, the present method for manufacturing a power device includes the steps of preparing a conductive-layer-joined metal-made support substrate in which a group III nitride conductive layer is joined to a metal-made support substrate, forming a group III nitride active layer on the group III nitride conductive layer, and forming an electrode on the group III nitride active layer. Thus, an inexpensive power device low in on-resistance and a method for manufacturing the same can be provided.

### BACKGROUND OF THE INVENTION

1. Field of the Invention

The present invention relates to a power device including a group III nitride layer and a method for manufacturing the same, and specifically to an inexpensive power device low in on-resistance and a method for manufacturing the same.

2. Description of the Background Art

A power device made of a group III nitride material such as GaN has recently vigorously been developed. Such a group III nitride power device is excellent in low loss (low on-resistance) and in its capability of operation at high temperature, as compared with a power device made of a silicon material. In addition, a power device preferably has a vertical structure in which an electrode portion is formed on each of opposing main surfaces, in terms of advantages in greater current and higher blocking voltage and ease in routing of an interconnection. Therefore, in a vertical device (referring to a device having a vertical structure; to be understood similarly hereinafter) such as a Schottky barrier diode (hereinafter also referred to as an SBD), a PN diode (hereinafter also referred to as a PND), and a MIS (metal-insulator-semiconductor) transistor, an active layer (referring to a layer exhibiting a device function; to be understood similarly hereinafter) has been formed on a main surface of a conductive GaN substrate.

For example, Tanabe et al., “GaN Epitaxial Growth on GaN substrate and Application to Power Device,” SEI Technical Review, Sumitomo Electric Industries, Ltd., No. 170, January 2007, pp. 34-39 discloses an SBD and a PND each having a vertical structure in which an active layer is formed on a main surface of a conductive GaN substrate. In addition, Hirotaka Otake et al., “Vertical GaN-Based Trench Gate Metal Oxide Semiconductor Field-Effect Transistors GaN Bulk Substrates,” Applied Physics Express, 1, The Japan Society of Applied Physics, 2008, pp. 011105-1-011105-3 discloses a MOSFET (a metal oxide semiconductor field effect transistor representing one type of MIS transistors) having a vertical structure in which an active layer is formed on a main surface of a conductive GaN substrate.

### SUMMARY OF THE INVENTION

The vertical devices (such as an SBD, a PND and a MOSFET) disclosed in aforementioned Tanabe et al., “GaN Epitaxial Growth on GaN substrate and Application to Power Device,” SEI Technical Review, Sumitomo Electric Industries, Ltd., No. 170, January 2007, pp. 34-39 and Hirotaka Otake et al., “Vertical GaN-Based Trench Gate Metal Oxide Semiconductor Field-Effect Transistors GaN Bulk Substrates,” Applied Physics Express, 1, The Japan Society of Applied Physics, 2008, pp. 011105-1 011105-3, however, each include a free-standing substrate as a conductive GaN substrate, and a sufficient thickness is required in order to ensure free-standing capability of the substrate. Here, although depending also on a size of a substrate, a thickness sufficient for ensuring free-standing capability of a conductive free-standing GaN substrate is not smaller than approximately 200 μm and preferably not smaller than approximately 300 μm, for example, in a substrate having a diameter of 2 inches (50.8 mm). In addition, the conductive free-standing GaN substrate normally has specific resistance of approximately 1×10⁻² Ω·cm, even though it is conductive. Therefore, in the vertical device including the conductive free-standing GaN substrate as the substrate, a resistance component of the conductive free-standing GaN substrate is unignorable and it has been difficult to lower on-resistance. Moreover, since a rate of growth of a GaN crystal is low, a conductive free-standing GaN substrate is expensive and hence it has been difficult to reduce cost for a vertical device including a conductive free-standing GaN substrate as the substrate.

An object of the present invention is to solve the problems above and to provide an inexpensive power device having low on-resistance and a method for manufacturing the same.

According to one aspect, the present invention is directed to a power device including a metal-made support substrate, and a group III nitride conductive layer, a group III nitride active layer and an electrode successively formed on one main surface side of the metal-made support substrate.

In the power device according to the present invention, the metal-made support substrate can have a difference between a coefficient of thermal expansion of the metal-made support substrate and a coefficient of thermal expansion of the group III nitride conductive layer not greater than 4.5×10⁻⁶ K⁻¹ and a melting point higher than 1100° C., and it can chemically be stable against an NH₃ gas and an H₂ gas in an atmosphere not higher than 1100° C. Here, the metal-made support substrate can contain any element selected from the group consisting of Mo, W and Ta.

In addition, in the power device according to the present invention, the metal-made support substrate can include a metal underlying substrate and at least one metal layer formed on one main surface of the metal underlying substrate. Here, the metal underlying substrate can contain any element selected from the group consisting of Mo, W and Ta, and the metal layer can contain any element selected from the group consisting of W, Ti and Ta.

Moreover, in the power device according to the present invention, the group III nitride conductive layer can have a thickness not smaller than 0.05 μm and not greater than 100 μm.

Further, according to another aspect, the present invention is directed to a method for manufacturing a power device including the steps of: preparing a conductive-layer-joined metal-made support substrate in which a group III nitride conductive layer is joined to a metal-made support substrate; forming a group III nitride active layer on the group III nitride conductive layer; and forming an electrode on the group III nitride active layer. Here, a temperature at which the group III nitride active layer is formed can be not lower than 700° C.

According to the present invention, an inexpensive power device having low on-resistance and a method for manufacturing the same can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a basic structure of a power device according to the present invention.

FIG. 2 is a schematic cross-sectional view showing a basic structure of a conventional and typical power device.

FIG. 3 is a schematic cross-sectional view showing one example of the power device according to the present invention.

FIG. 4 is a schematic cross-sectional view showing one example of the conventional and typical power device.

FIG. 5 is a schematic cross-sectional view showing another example of the power device according to the present invention.

FIG. 6 is a schematic cross-sectional view showing another example of the conventional and typical power device.

FIG. 7 is a schematic cross-sectional view showing yet another example of the power device according to the present invention.

FIG. 8 is a schematic cross-sectional view showing yet another example of the conventional and typical power device.

FIG. 9 is a flowchart showing an exemplary method for manufacturing a power device according to the present invention.

FIG. 10 is a flowchart showing an exemplary method for manufacturing a conventional and typical power device.

FIG. 11 is a schematic cross-sectional view showing one example of the step of preparing a conductive-layer-joined metal-made support substrate in the method for manufacturing a power device according to the present invention, in which (a) shows a joint sub step and (b) shows a separation sub step.

FIG. 12 is a schematic cross-sectional view showing another example of the step of preparing a conductive-layer-joined metal-made support substrate in the method for manufacturing a power device according to the present invention, in which (a) shows an ion implantation sub step, (b) shows a joint sub step, and (c) shows a separation sub step.

FIG. 13 is a graph showing forward current-voltage characteristics of the power device according to the present invention and the conventional and typical power device.

FIG. 14 is a graph showing reverse current-voltage characteristics of the power device according to the present invention and the conventional and typical power device.

### DESCRIPTION OF THE PREFERRED EMBODIMENTS

### First Embodiment

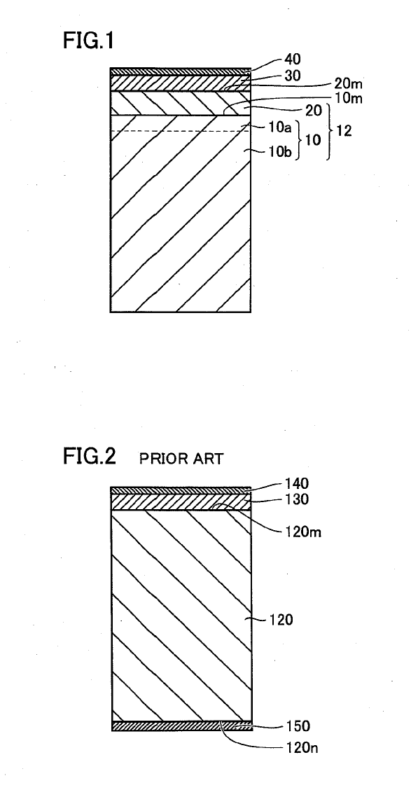

Referring to FIG. 1, one embodiment of a power device according to the present invention includes a metal-made support substrate 10, and a group III nitride conductive layer 20, a group III nitride active layer 30 and an electrode 40 successively formed on a side of one main surface 10m of metal-made support substrate 10. Here, the active layer refers to a layer exhibiting a function of that power device, and it may be implemented by a single layer or a plurality of layers. In addition, the group III nitride refers to a nitride of a group III element and examples thereof include GaN, MN, AlGa₁₋ₚN (0<p<1), InN, In_{q}Ga_{1-q}N (0<q<1), and the like.

Meanwhile, referring to FIG. 2, a conventional and typical power device includes a group III nitride active layer 130 and an active-layer-side electrode 140 successively formed on a side of one main surface 120m of a conductive free-standing group III nitride substrate 120 (for example, a conductive free-standing GaN substrate) and a substrate-side electrode 150 formed on a side of the other main surface 120n of conductive free-standing group III nitride substrate 120. Here, the conductive free-standing group III nitride substrate has a thickness sufficient for ensuring free-standing capability. For example, a conductive free-standing group III nitride substrate having a diameter of 2 inches (50.8 mm) has a thickness not smaller than approximately 200 μm and preferably not smaller than approximately 300 μm. In addition, the conductive free-standing group III nitride substrate normally has specific resistance approximately from 1×10⁻³ Ω·cm to 1 Ω·cm, even though it is conductive. Therefore, in the conventional and typical power device, a resistance component of the conductive free-standing GaN substrate is unignorable and it has been difficult to lower on-resistance. Moreover, since a rate of growth of a group III nitride crystal is low, a conductive free-standing group III nitride substrate is expensive and hence it has been difficult to reduce cost for the conventional and typical power device.

Referring to FIGS. 1 and 2, as compared with the conventional and typical power device described above, the power device according to the present embodiment includes metal-made support substrate 10 extremely lower in specific resistance than the conductive group III nitride. Therefore, even if the power device according to the present embodiment does not include conductive free-standing group III nitride substrate 120 that has been included in the conventional and typical power device, metal-made support substrate 10 can support any of group III nitride conductive layer 20 smaller in thickness, group III nitride active layer 30 and electrode 40. Here, metal-made support substrate 10 has specific resistance normally (in a range) from 1×10⁻⁶ Ω·cm to 1×10⁻⁴ Ω·cm which is extremely lower than that of a conductive group III nitride (for example, conductive GaN), that is, it is low in resistance even though it has a large thickness. In addition, group III nitride conductive layer 20 which is expensive and has specific resistance in a range approximately from 1×10⁻³ Ω·cm to 1 Ω·cm is extremely smaller in thickness than conductive free-standing group III nitride substrate 120. Therefore, the power device according to the present embodiment is more inexpensive and lower in on-resistance than the conventional and typical power device. Here, specific resistance is measured with a Hall effect measurement apparatus and on-resistance is measured with a semiconductor parameter analyzer.

In the power device according to the present embodiment, though a thickness of group III nitride conductive layer 20 is not particularly restricted, from a point of view of ease in formation of group III nitride conductive layer 20 by joint on main surface 10m of metal-made support substrate 10, a thickness not smaller than 0.05 μm is preferred and a thickness not smaller than 0.1 μm is further preferred. In addition, though a thickness of group III nitride conductive layer 20 is not particularly restricted, from a point of view of lowering in on-resistance of the power device, a thickness not greater than 100 μm is preferred, a thickness not greater than 30 μm is further preferred, and a thickness not greater than 10 μm is still further preferred.

In the power device according to the present embodiment, from a point of view of ensuring joint between metal-made support substrate 10 and group III nitride conductive layer 20, metal-made support substrate 10 is preferably has a difference between a coefficient of thermal expansion of metal-made support substrate 10 and a coefficient of thermal expansion of group III nitride conductive layer 20 not greater than 4.5×10⁻⁶ K⁻¹. In addition, from a point of view of absence of melting in formation of group III nitride active layer 30 on main surface 20m of group III nitride conductive layer 20, metal-made support substrate 10 has a melting point preferably higher than 1100° C. and further preferably higher than 1200° C. Moreover, from a point of view of prevention of introduction into group III nitride conductive layer 20 and group III nitride active layer 30 in formation of group III nitride active layer 30 on main surface 20m of group III nitride conductive layer 20, metal-made support substrate 10 is preferably chemically stable against an NH₃ gas and an H₂ gas in an atmosphere not higher than 1100° C. and further preferably chemically stable against an NH₃ gas and an H₂ gas in an atmosphere not higher than 1200° C. Here, being chemically stable against an NH₃ gas and an H₂ gas means that decomposition, chemical reaction or the like due to the NH₃ gas and the H₂ gas does not occur from a surface to the inside of the substrate, or that, even though the surface of the substrate chemically reacts with the NH₃ gas and the H₂ gas, a product of chemical reaction does not cause decomposition, chemical reaction or the like and it has resistance to the NH₃ gas and the H₂ gas.

TABLE 1

| | | Specific | Coefficient of | Melting | |
|---|---|---|---|---|---|
| | | Resistance | Thermal Expansion | Point | Stability Against |
| | | (×10⁻⁶ Ω · cm) | (×10⁻⁶ K⁻¹) | (°C.) | NH₃ Gas and H₂ Gas |
| Group III | GaN | — | 5.6 | — | — |
| Nitride | | | (Direction of a Axis) | | |
| | AlN | — | 4.2 | — | — |
| | | | (Direction of a Axis) | — | — |
| | InN | — | Approximately 4.0 | | |
| | | | (Direction of a Axis) | | |
| Metal | Mo | 5.7 | 5.1 | 2610 | Good |
| | W | 5.4 | 4.5 | 3387 | Good |
| | Ta | 13.5 | 6.5 | 2996 | Good |
| | Ti | 54.0 | 8.9 | 1675 | Poor |
| | Al | 2.7 | 23.5 | 660 | Poor |

Here, Table 1 summarizes various characteristics values of group III nitrides and metals used in the power device according to the present embodiment. Referring to Table 1, examples of metals satisfying the conditions above and suitably used for metal-made support substrate 10 include Mo, W, Ta, alloys thereof, and the like. Namely, metal-made support substrate 10 preferably contains any element selected from the group consisting of Mo, W, and Ta.

In addition, from a point of view of an enhanced joint characteristic between metal-made support substrate 10 and group III nitride conductive layer 20 in the power device according to the present embodiment, metal-made support substrate 10 preferably includes a metal underlying substrate 10b and at least one metal layer 10a formed on one main surface of metal underlying substrate 10b.

When metal-made support substrate 10 includes metal underlying substrate 10b and metal layer 10a, normally, metal underlying substrate 10b is extremely greater in thickness than metal layer 10a. Therefore, the characteristics of metal-made support substrate 10 is determined substantially by the characteristics of metal underlying substrate 10b. From such a point of view, metal underlying substrate 10b preferably has such characteristics suitable for metal-made support substrate 10 that a difference between a coefficient of thermal expansion of the metal underlying substrate and a coefficient of thermal expansion of the group III nitride conductive layer is not greater than 4.5×10⁻⁶ K⁻¹ and the metal underlying substrate has a melting point higher than 1100° C. and is chemically stable against an NH₃ gas and an H₂ gas in an atmosphere not higher than 1100° C. From such a point of view, a metal suitably used for metal-made support substrate 10 is preferred as a metal used for metal underlying substrate 10b. Therefore, examples of metals suitably used for metal underlying substrate 10b include Mo, W, Ta, alloys thereof, and the like. Namely, metal underlying substrate 10b preferably contains any element selected from the group consisting of Mo, W and Ta.

Since metal layer 10a is joined to group III nitride conductive layer 20, it may have a melting point not higher than 1100° C. from a point of view of absence of problem of melting, and it may not be chemically stable against an NH₃ gas and an H₂ gas from a point of view of absence of contact with the NH₃ gas and the H₂ gas in formation of a group III nitride active layer. From such a point of view, examples of metals used for metal layer 10a include not only Mo, W, Ta, Ti, V, Zr, Nb, Hr, alloys thereof; and the like but also Al, Mn, Fe, Cu, Ga, Y, alloys thereof, and the like. Further, from a point of view of high joint strength with a group III nitride conductive layer formed of a group III nitride semiconductor, metal layer 10a preferably contains any element selected from the group consisting of W, Ti and Ta and further preferably it is made of W, Ti, Ta, and an alloy thereof.

Referring to FIG. 1, the power device according to the present embodiment specifically includes group III nitride conductive layer 20 formed on one main surface 10m of metal-made support substrate 10, group III nitride active layer 30 formed on main surface 20m of group III nitride conductive layer 20, and electrode 40 formed on group III nitride active layer 30.

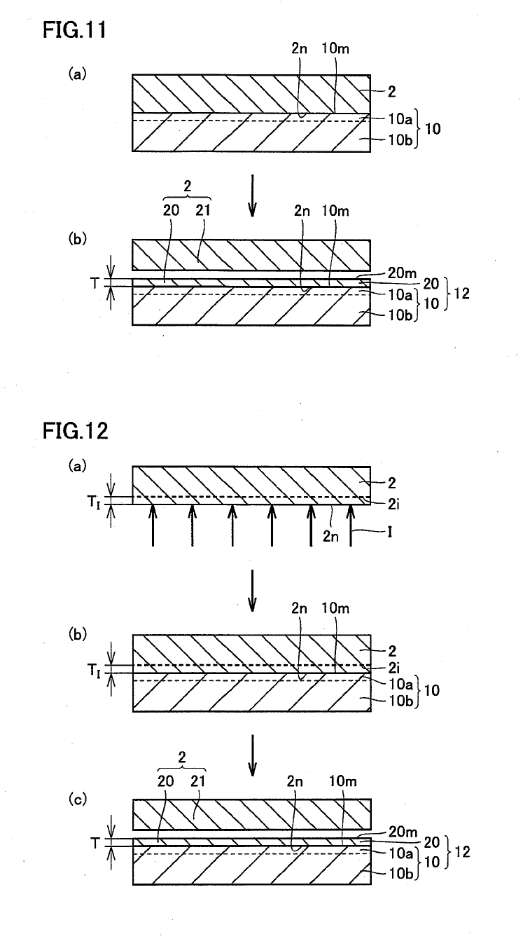

Here, a method of forming group III nitride conductive layer 20 is not particularly restricted, however, from a point of view of forming group III nitride conductive layer 20 having a small thickness and good crystallinity, referring to FIGS. 11 and 12, preferably, one main surface 2n of a group III nitride conductive substrate 2 is joined to one main surface 10m of the metal-made support substrate and thereafter group III nitride conductive substrate 2 is separated at a position at a prescribed depth T from one main surface 2n. In addition, referring to FIG. 1, a method of forming group III nitride active layer 30 is not particularly restricted, however, from a point of view of forming group III nitride active layer 30 having a small thickness and good crystallinity, group III nitride active layer 30 is preferably epitaxially grown on main surface 20m of group III nitride conductive layer 20. Moreover, a method of forming electrode 40 is not particularly restricted, however, from a point of view of establishing good electrical contact with group III nitride active layer 30, electrode 40 is preferably formed on group III nitride active layer 30 with a vacuum vapor deposition method, a sputtering method, and the like. It is noted that metal-made support substrate 10 may include metal underlying substrate 10b and at least one metal layer 10a formed on one main surface of metal underlying substrate 10b.

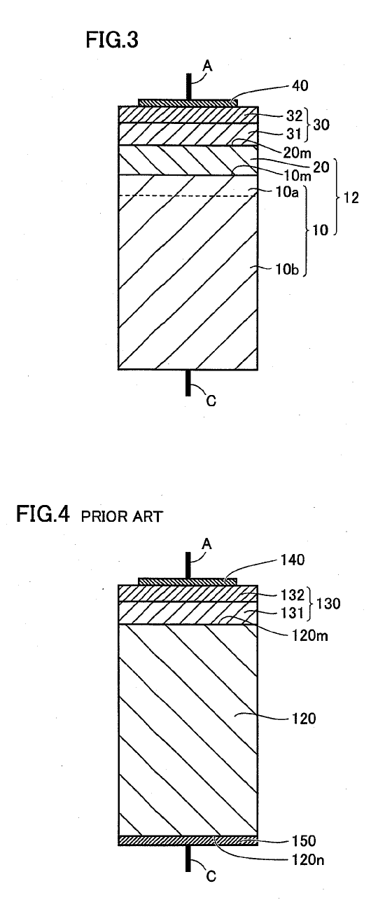

Referring to FIG. 3, an SBD representing one example of the power device according to the present embodiment includes an n⁺-GaN layer formed as group III nitride conductive layer 20 on one main surface 10m of metal-made support substrate 10, an n⁺-GaN layer 31 and an n-GaN layer 32 successively formed as group III nitride active layer 30 on main surface 20m of the n⁺-GaN layer (group III nitride conductive layer 20), and a Schottky electrode formed as electrode 40 on n-GaN layer 32. Here, n⁺-GaN layer 31 may not be provided. In the present SBD, metal-made support substrate 10 is connected as a cathode C and the Schottky electrode (electrode 40) is connected as an anode A.

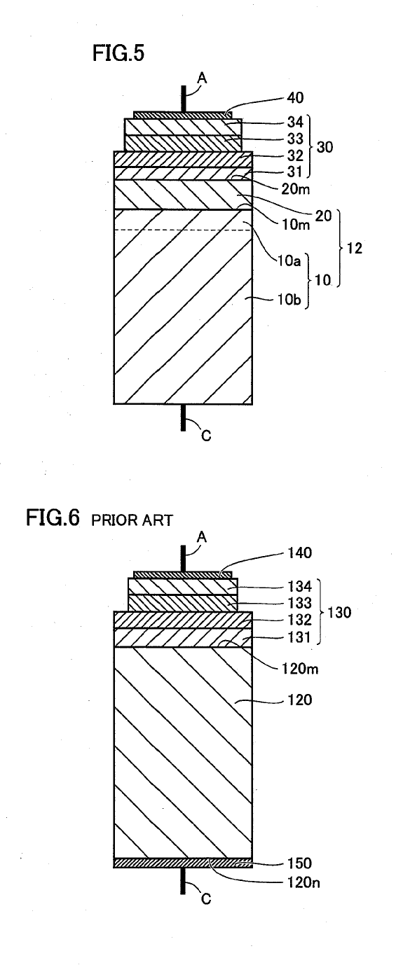

Referring to FIG. 5, a PND representing another example of the power device according to the present embodiment includes an n⁺-GaN layer formed as group III nitride conductive layer 20 on one main surface 10m of metal-made support substrate 10, n⁺-GaN layer 31, n-GaN layer 32, a p-GaN layer 33, and a p⁺-GaN layer 34 successively formed as group III nitride active layer 30 on main surface 20m of the n⁺-GaN layer (group III nitride conductive layer 20), and a p-ohmic electrode formed as electrode 40 on p⁺-GaN layer 34. Here, n⁺-GaN layer 31 may not be provided. In the present PND, metal-made support substrate 10 is connected as cathode C and the p-ohmic electrode (electrode 40) is connected as anode A.

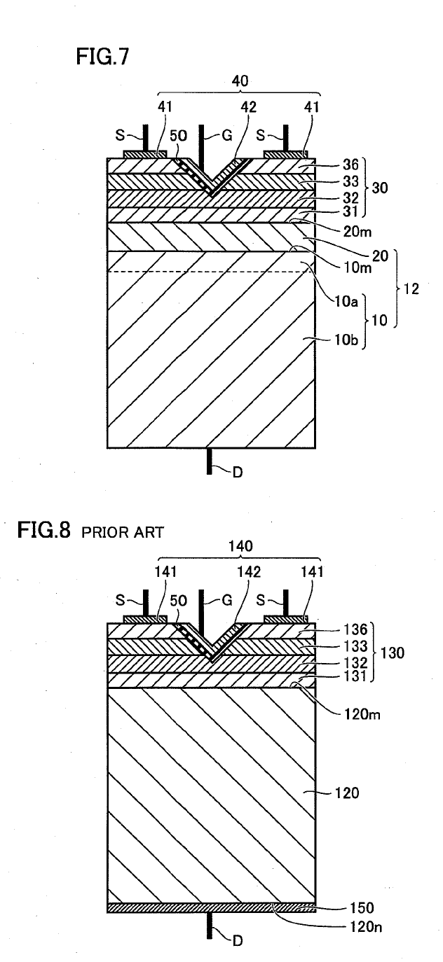

Referring to FIG. 7, a MIS (metal-insulator-semiconductor) transistor representing yet another example of the power device according to the present embodiment includes an n⁺-GaN layer formed as group III nitride conductive layer 20 on one main surface 10m of metal-made support substrate 10, n⁺-GaN layer 31, n-GaN layer 32, p-GaN layer 33, and an n⁺-GaN layer 36 successively formed as group III nitride active layer 30 on main surface 20m of the n⁺-GaN layer (group III nitride conductive layer 20), and a source electrode 41 and a gate electrode 42 formed as electrode 40 on group III nitride active layer 30. Here, source electrode 41 is formed on a part of the main surface of n⁺-GaN layer 36. In addition, n⁺-GaN layer 36, p-GaN layer 33 and n-GaN layer 32 of group III nitride active layer 30 are etched to form a mesa shape, an insulating layer 50 is formed on the etched portion, and gate electrode 42 is formed on insulating layer 50. N⁺-GaN layer 31 may not be provided. In the present MIS transistor, metal-made support substrate 10 is connected as a drain D, source electrode 41 is connected as a source S, and gate electrode 42 is connected as a gate G.

### Second Embodiment

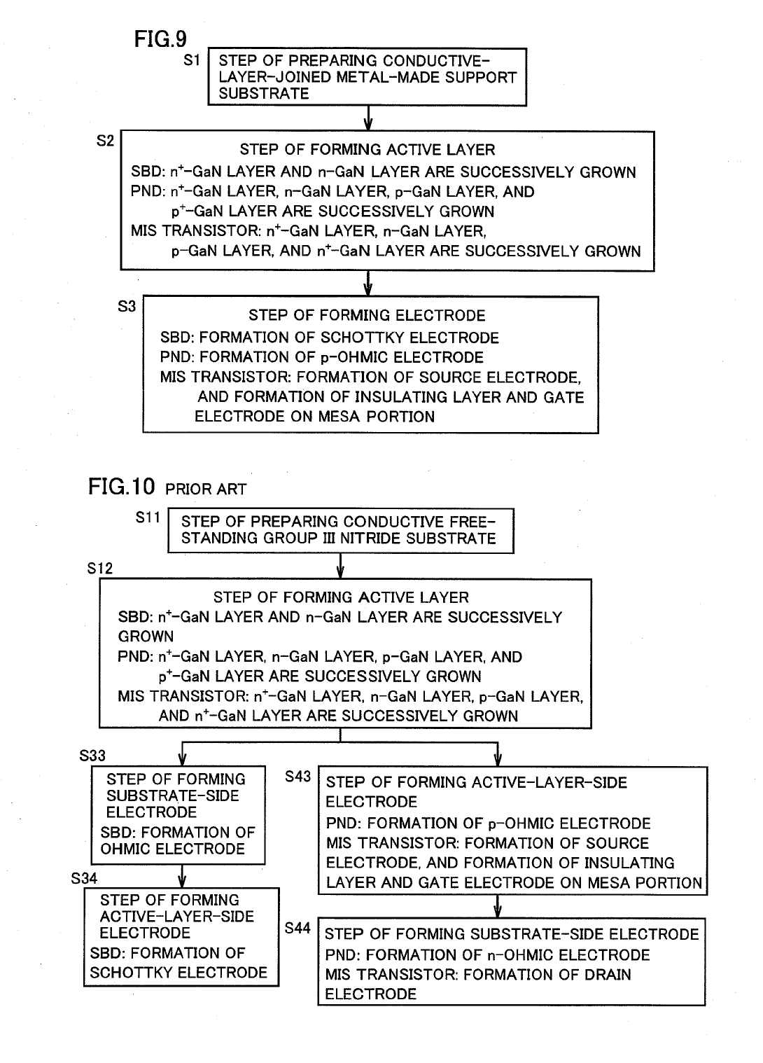

Referring to FIGS. 1 and 9, a method for manufacturing a power device according to the present invention includes the steps of preparing a conductive-layer-joined metal-made support substrate 12 in which group III nitride conductive layer 20 is joined to metal-made support substrate 10 (S1), forming group III nitride active layer 30 on group III nitride conductive layer 20 (S2), and forming electrode 40 on group III nitride active layer 30 (S3). According to the method for manufacturing a power device in the present embodiment, an inexpensive power device low in on-resistance can be obtained.

The method for manufacturing a power device according to the present embodiment includes the step of preparing conductive-layer-joined metal-made support substrate 12 (S1). According to the present step, conductive-layer-joined metal-made support substrate 12 having a conductive layer of good crystallinity is obtained with low cost. The step of preparing conductive-layer-joined metal-made support substrate 12 (S1) is not particularly restricted, however, from a point of view of ease in achieving a uniform thickness of the conductive layer, the following two examples are preferably carried out.

Referring to FIG. 11, an exemplary step of preparing conductive-layer-joined metal-made support substrate 12 includes a joint sub step of bonding and joining one main surface 2n of group III nitride conductive substrate 2 and one main surface 10m of metal-made support substrate 10 to each other as shown in FIG. 11(a) and a separation sub step of separating group III nitride conductive substrate 2 at a plane at depth T from main surface 2n of group III nitride conductive substrate 2 (plane in parallel to main surface 2n) as shown in FIG. 11(b). Through these steps, conductive-layer-joined metal-made support substrate 12 in which group III nitride conductive layer 20 having thickness T is joined onto main surface 10m of metal-made support substrate 10 is obtained.

Here, a method of joining one main surface 2n of group III nitride conductive substrate 2 and one main surface 10m of metal-made support substrate 10 to each other is not particularly restricted, however, a direct joint method of cleaning a surface to be bonded, carrying out direct bonding, and carrying out joint at a raised temperature of 600° C. to 1200° C. after bonding, a surface activation method of activating a bonding surface with plasma, ions or the like and carrying out joint, and the like are preferably employed.

Here, a method of separating group III nitride conductive substrate 2 at a plane at depth T from main surface 2n (plane in parallel to main surface 2n) is not particularly restricted, and the substrate can mechanically be separated by using an electric spark machine, a wire saw, an inner peripheral cutting edge, an outer peripheral cutting edge, laser irradiation, and the like. In such a mechanical separation method, it is difficult to set thickness T of group III nitride conductive layer 20 on metal-made support substrate 10 to 10 μm or smaller, and normally, this is a method suitable for manufacturing conductive-layer-joined metal-made support substrate 12 of which group III nitride conductive layer 20 has a thickness not smaller than 10 μm.

Referring to FIG. 12, another example of the step of preparing conductive-layer-joined metal-made support substrate 12 includes an ion implantation sub step of implanting ions I of hydrogen, helium, nitrogen, oxygen, argon, or the like in a plane 2i at a depth T_{I} from one main surface 2n of group III nitride conductive substrate 2 (plane in parallel to main surface 2n) as shown in FIG. 12(a), a joint sub step of joining one main surface 2n of group III nitride conductive substrate 2 in which ions were implanted and one main surface 10m of metal-made support substrate 10 to each other as shown in FIG. 12(b), and a separation sub step of separating group III nitride conductive substrate 2 at a plane at depth T_{I} from main surface 2n (plane in parallel to main surface 2n) by applying force to metal-made support substrate 10 and group III nitride conductive substrate 2 as shown in FIG. 12(c).

Through the steps above, conductive-layer-joined metal-made support substrate 12 in which group III nitride conductive layer 20 having thickness T is joined onto main surface 10m of metal-made support substrate 10 is obtained. Here, thickness T of group III nitride conductive layer 20 of conductive-layer-joined metal-made support substrate 12 is substantially equal to ion implantation depth T_{I} above. In addition, in the ion implantation sub step above, from a point of view of mitigating damage of the substrate, ions small in radius are preferred and hydrogen ions are most preferred. Moreover, force applied to metal-made support substrate 10 and group III nitride conductive layer 20 in the separation sub step includes not only direct force but also indirect force such as stress caused by heat treatment.

Such a method is suitable for manufacturing a conductive-layer-joined metal support substrate including group III nitride conductive layer 20 having small thickness T, for example, in a range approximately from 0.05 μm to 30 μm, because this method makes use of such a fact that an ion implanted portion in group III nitride conductive substrate 2 is embrittled and ion implantation depth T₁ can be adjusted with high accuracy.

In addition, referring to FIGS. 11 and 12, even when metal-made support substrate 10 includes metal underlying substrate 10b and at least one metal layer 10a, conductive-layer-joined metal-made support substrate 12 is obtained in a manner as described above.

The method for manufacturing a power device according to the present embodiment includes the step of forming the group III nitride active layer (S2). Through the present step, group III nitride active layer 30 having good crystallinity is formed on group III nitride conductive layer 20 having good crystallinity. A method of forming group III nitride active layer 30 is not particularly restricted, however, from a point of view of growing group III nitride active layer 30 having good crystallinity, such vapor phase methods as an MOCVD (metal organic chemical vapor deposition) method, an HVPE (hydride vapor phase epitaxy) method, and an MBE (molecular beam epitaxy) method are preferably employed. In addition, the MOCVD method is further preferably employed, from a point of view of ease in adjustment of a growth rate of group III nitride active layer 30. A temperature for forming group III nitride active layer 30 is different depending on a chemical composition of a group III nitride and it is not particularly restricted, however, from a point of view of obtaining an active layer having good crystallinity, a temperature not lower than 700° C. is preferred and a temperature not lower than 950° C. is further preferred.

Here, group III nitride active layer 30 to be formed is different depending on a type of a power device. Referring to FIGS. 3 and 9, in manufacturing an SBD, n⁺-GaN layer 31 and n-GaN layer 32 are successively grown as group III nitride active layer 30 on main surface 20m of group III nitride conductive layer 20. In addition, referring to FIGS. 5 and 9, in manufacturing a PND, n⁺-GaN layer 31, n-GaN layer 32, p-GaN layer 33, and p⁺-GaN layer 34 are successively grown as group III nitride active layer 30 on main surface 20m of group III nitride conductive layer 20. Moreover, referring to FIGS. 7 and 9, in manufacturing a MIS transistor, n⁺-GaN layer 31, n-GaN layer 32, p-GaN layer 33, and n⁺-GaN layer 36 are successively grown as group III nitride active layer 30 on main surface 20m of group III nitride conductive layer 20. It is noted that n⁺-GaN layer 31 can be omitted in manufacturing an SBD in FIG. 3, a PND in FIG. 5 and a MIS transistor in FIG. 7.

The method for manufacturing a power device according to the present embodiment includes the step of forming an electrode (S3). The electrode formed in the present step means electrode 40 formed on the main surface of group III nitride active layer 30. A method of forming such electrode 40 is not particularly restricted, however, from a point of view of ease in controlling a thickness of the electrode and ease in achieving a uniform thickness of the electrode, an electron beam (EB) vapor deposition method, a resistance heating vapor deposition method, a sputtering method, and the like are preferred. Since the power device manufactured with the manufacturing method according to the present embodiment includes metal-made support substrate 10 joined to group III nitride conductive layer 20, an electrode on a substrate side is not necessary. Therefore, the step of forming an electrode on the substrate side is not necessary.

Here, electrode 40 to be formed is different depending on a type of a power device. Referring to FIGS. 3 and 9, in manufacturing an SBD, a Schottky electrode is formed as electrode 40 on n-GaN layer 32 of group III nitride active layer 30. Referring to FIGS. 5 and 9, in manufacturing a PND, a p-ohmic electrode is formed as electrode 40 on p⁺-GaN layer 34 of group III nitride active layer 30. Referring to FIGS. 7 and 9, in manufacturing a MIS transistor, as electrodes 40, source electrode 41 is formed on a part of n⁺-GaN layer 36 of group III nitride active layer 30, and n⁺-GaN layer 36, p-GaN layer 33 and n-GaN layer 32 of group III nitride active layer 30 are etched to form a mesa shape, insulating layer 50 is formed on the etched portion, and gate electrode 42 is formed on insulating layer 50.

### Example A

An example where an SBD was manufactured as a power device will be described as an Example A. Example A includes Examples A1 to A8 and a Comparative Example RA1 as follows.

### Example A1

1. Preparation of Conductive-Layer-Joined Metal-Made Support Substrate

Referring first to FIGS. 3, 9 and 11, a GaN-conductive-layer-joined Mo support substrate (conductive-layer-joined metal-made support substrate 12) in which a GaN conductive layer (group III nitride conductive layer 20) was joined to a Mo support substrate (metal-made support substrate 10) was prepared as follows (the step of preparing a conductive-layer-joined metal-made support substrate S1).

Initially, a GaN ingot was grown with the HVPE method. The GaN ingot was formed with an n-type GaN crystal doped with oxygen and had carrier concentration of approximately 5×10¹⁸ cm⁻³. The GaN ingot had a diameter of 2 inches (50.8 mm), a thickness of 1 mm, and a main surface having an off angle of 0.5° with respect to the (0001) plane. Here, the carrier concentration was measured with a Hall effect measurement apparatus.

Thereafter, an outer circumference of the GaN ingot was shaped by cylindrical grinding. Further, a front main surface (a Ga atomic plane) of the GaN ingot was subjected to mirror polishing and thereafter a back main surface (an N atomic plane) was subjected to mirror polishing. In mirror polishing, mechanical polishing using diamond slurry was performed and thereafter chemical-mechanical polishing was performed. Working was performed such that surface roughness Ra (referring to arithmetic mean roughness Ra defined in JIS B0601; to be understood similarly hereinafter) is 2 nm or smaller, surface roughness P-V (Peak To Valley; referring to a difference in height between a highest location and a lowest location of the surface; to be understood similarly hereinafter) is 10 nm or smaller, a total thickness variation TTV (referring to a difference between a highest location and a lowest location, from a reference surface to the other main surface, with a plane resulting from vacuum sucking of one main surface of a substrate being defined as the reference plane; to be understood similarly hereinafter) is 30 μm or smaller, and warp is not greater than 30 μm. Here, surface roughnesses Ra and P-V of the GaN substrate in a range of 80 μm square were measured with Micromap of Ryoka Systems Inc., and total thickness variation TTV was measured with a flatness tester of Nidek Co., Ltd.

Then, the GaN ingot was cleaned. Initially, ultrasonic cleaning with IPA (isopropyl alcohol; to be understood similarly hereinafter) heated to 60° C. was performed for 10 minutes. Then, cleaning with an SC-1 liquid (an NH₄OH/H₂O₂/H₂O liquid mixture) heated to 70° C. was performed for 10 minutes. Then, rinsing with pure water was performed for 10 minutes. Then, cleaning with an SC-2 liquid (an HCl/H₂O₂/H₂O liquid mixture) heated to 70° C. was performed for 10 minutes. Then, rinsing with pure water was performed for 10 minutes. Then, cleaning with dilute hydrofluoric acid was performed for 5 minutes. Then, cleaning with aqua regia was performed for 5 minutes. Then, rinsing with pure water was performed for 10 minutes. Then, steam drying of IPA was performed for 10 minutes.

Then, the back main surface (N atomic plane) (main surface 2n) of the cleaned GaN ingot was activated by RIE (reactive ion etching). Namely, under a pressure of 1 Pa, a surface layer of the back main surface of the GaN ingot was etched by 1 nm with argon plasma. Then, one main surface of the Mo support substrate (metal-made support substrate 10) having a thickness of 500 μm that had been subjected to polishing of both main surfaces was etched with argon plasma.

Then, the back main surface (N atomic plane) (main surface 2n) of the GaN ingot (group III nitride conductive substrate 2) etched with argon plasma and the main surface of the Mo support substrate (metal-made support substrate 10) etched with argon plasma were joined to each other. Specifically, the GaN ingot and the Mo support substrate were bonded to each other and held for 5 minutes at a pressure of 1000 N/cm² at an atmospheric temperature of 100° C. In addition, annealing was performed at 1100° C. in a nitrogen atmosphere for 30 minutes or longer. In this annealing, a temperature was increased and decreased at a rate not greater than 100° C./min.

Then, the GaN ingot was sliced so as to form a GaN conductive layer having a thickness of 120 μm on the Mo support substrate. Slicing was performed by using an upper-cut-type multi-wire saw including a brass-plated wire having a diameter of 0.07 mm and high-concentration oil diamond slurry. A speed of the wire was set to 500 m/min. on average and a feed rate of the ingot was set to 1 to 1.5 mm/hr. In addition, wire tension was set to 10 N. The GaN-conductive-layer-joined Mo support substrate was thus obtained. Regarding the obtained GaN-conductive-layer-joined Mo support substrate, joint strength between the support substrate and the conductive layer was measured in a tensile test, and it was good, that is, not lower than 5 MPa (GaN conductive layer failure at a joint interface).

Then, the front main surface (Ga atomic plane) of the GaN-conductive-layer-joined Mo support substrate was subjected to mirror polishing. In mirror polishing, chemical-mechanical polishing was performed after mechanical polishing using diamond slurry. Working was performed such that surface roughness Ra after polishing was 1.5 nm. Thus, the GaN conductive layer on the Mo support substrate had a thickness of 100 μm. In mechanical polishing, a surface plate made of tin and having a diameter of 450 mm was employed. The number of revolutions of the surface plate was set to 40 rpm. Water-soluble polycrystalline diamond slurry was employed as a working fluid. Abrasive grains in the slurry each had a grain size of 0.5 μm or smaller. Load was set to 250 gf/cm². In chemical-mechanical polishing, a surface plate having a diameter of 450 mm was employed. Unwoven fabric was employed for a polishing pad. The number of revolutions of the surface plate was set to 40 rpm. A liquid mixture of colloidal silica and nanodiamond was employed as a working fluid. Load was set to 250 gf/cm².

Then, the surface of the GaN conductive layer was cleaned. Specifically, initially, ultrasonic cleaning with IPA heated to 60° C. was performed for 10 minutes. Then, cleaning with the SC-1 liquid (NH₄OH/H₂O₂/H₂O liquid mixture) heated to 70° C. was performed for 10 minutes. Then, rinsing with pure water was performed for 10 minutes. Then, cleaning with the SC-2 liquid (HCl/H₂O₂/H₂O liquid mixture) heated to 70° C. was performed for 10 minutes. Then, rinsing with pure water was performed for 10 minutes. Then, cleaning with dilute hydrofluoric acid was performed for 5 minutes. Then, rinsing with pure water was performed for 10 minutes. Then, steam drying of IPA was performed for 10 minutes. Thus, the GaN-conductive-layer-joined Mo support substrate (conductive-layer-joined metal-made support substrate 12) including the GaN conductive layer having a thickness of 100 μm was prepared.

2. Formation of Active Layer

Referring next to FIGS. 3 and 9, n⁺-GaN layer 31 having a function as a stop layer, carrier concentration of 1×10¹⁸ cm⁻³, and a thickness of 0.5 μm, and n-GaN layer 32 having a function as a drift layer, carrier concentration of 7×10¹⁵ cm⁻³, and a thickness of 5 μm were successively grown as group III nitride active layer 30 with the MOCVD method on the front main surface (Ga atomic plane) (main surface 20m) of the GaN-conductive-layer-joined Mo support substrate (conductive-layer-joined metal-made support substrate 12) (the step of forming an active layer S2). In growing the active layer above, a growth temperature was set to 1050° C., a growth pressure was set to 200 Torr (26.7 kPa), TMG (trimethylgallium) and the NH₃ (ammonia) gas were employed as a source gas, an SiH₄ (silane) gas was employed as a dopant gas, and an H₂ gas was employed as a carrier gas.

3. Formation of Electrode

Referring next to FIGS. 3 and 9, electrode 40 was formed on n-GaN layer 32 (the step of forming an electrode S3). Initially, the surface of n-GaN layer 32 was subjected to organic cleaning. Specifically, ultrasonic cleaning with acetone for 5 minutes, ultrasonic cleaning with IPA for 5 minutes, and ultrasonic cleaning with pure water for 5 minutes were successively performed, followed by drying with nitrogen gas blowing. Then, a Schottky electrode having a diameter of 200 μm was formed as electrode 40 on n-GaN layer 32, with photolithography, pre-treatment of the surface with a 10 mass % hydrochloric acid aqueous solution, and EB (electron beam) vapor deposition and lift-off of Ni/Au (an Ni layer having a thickness of 50 nm and an Au layer having a thickness of 300 nm). An SBD serving as a power device was thus obtained.

4. Characteristics of Power Device

Regarding the obtained SBD, on-resistance was measured with a semiconductor parameter analyzer, and it was as low as 1.18 mΩ·cm², a forward voltage Vf at current density of 500 A/cm² was as low as 1.33 V based on I-V (current-voltage) measurement using the semiconductor parameter analyzer, and a reverse blocking voltage at leakage current density of 1×10⁻³ A/cm² was as high as 354 V based on I-V (current-voltage) measurement using the semiconductor parameter analyzer. Table 2 summarizes the results.

### Example A2

The GaN-conductive-layer-joined Mo support substrate (conductive-layer-joined metal-made support substrate 12) was prepared as in Example Al except that the sliced GaN conductive layer (group III nitride conductive layer 20) had a thickness of 50 μm and the polished GaN conductive layer had a thickness of 30 μm. Regarding the obtained GaN-conductive-layer-joined Mo support substrate, joint strength between the support substrate and the conductive layer was good, that is, not lower than 5 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined Mo support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as the power device. Regarding the obtained SBD, on-resistance was as low as 1.11 mΩ·cm², forward voltage Vf at current density of 500 A/cm² was as low as 1.28 V, and a reverse blocking voltage at leakage current density of 1×10⁻³ A/cm² was as high as 330 V. Table 2 summarizes the results.

### Example A3

1. Preparation of Conductive-Layer-Joined Metal-Made Support Substrate

Referring first to FIGS. 3, 9 and 12, a GaN-conductive-layer-joined Mo support substrate (conductive-layer-joined metal-made support substrate 12) in which a GaN conductive layer (group III nitride conductive layer 20) was joined to a Mo support substrate (metal-made support substrate 10) was prepared as follows.

The GaN conductive substrate (group III nitride conductive substrate 2) grown with the HYPE method, cleaned, subjected to mirror polishing of both main surfaces, doped with oxygen, and having a diameter of 2 inches (50.8 mm) and a thickness of 500 μm was prepared as in Example A1. This GaN conductive substrate had a main surface having an off angle of 0.5° with respect to the (0001) plane and carrier concentration of approximately 5×10¹⁸ cm⁻³.

Hydrogen ions (ions I) were implanted from the side of the back main surface (N atomic plane) (main surface 2n) of this GaN conductive substrate (group III nitride conductive substrate 2). An acceleration voltage was set to 100 eV and a dose amount was set to 2.5×10¹⁷ cm⁻². A peak position of ion flow-in (plane 2i) was located at a depth of approximately 0.9 μm from the back main surface (main surface 2n). After hydrogen ion implantation, the surface of the GaN conductive substrate was cleaned.

The back main surface (N atomic plane) of the GaN conductive substrate (group III nitride conductive substrate 2) implanted with hydrogen ions and cleaned was brought in contact with plasma discharged in an Ar (argon) gas, to obtain a clean surface. Meanwhile, the main surface of the Mo support substrate (metal-made support substrate 10) subjected to polishing of both surfaces and having a thickness of 500 μm was brought in contact with plasma discharged in an Ar gas, to obtain a clean surface. Here, a condition for plasma discharge in the Ar gas was such that RF power was set to 100 W, an Ar gas flow rate was set to 50 sccm, and a pressure was set to 5.9 Pa. Then, the back main surface (N atomic plane) of the GaN conductive substrate which is the clean surface and the main surface of the Mo support substrate which is the clean surface were joined to each other by bonding in atmosphere. Since joint strength is low after bonding, joint strength was increased by heating the joined substrate for 2 hours at 300° C. in an N₂ gas.

In addition, by performing heating for 2 hours at 900° C. in the N₂ gas, the GaN conductive substrate (group III nitride conductive substrate 2) was separated at a plane at a depth of approximately 0.9 μm from the back main surface (main surface 2n) (plane in parallel to main surface 2n), and the GaN-conductive-layer-joined Mo support substrate (conductive-layer-joined metal-made support substrate 12) in which the GaN conductive layer (group III nitride conductive layer 20) was joined to the Mo support substrate (metal-made support substrate 10) was obtained. Then, by performing polishing, the GaN-conductive-layer-joined Mo support substrate including the GaN conductive layer having a thickness of 0.3 μm was obtained. Regarding the obtained GaN-conductive-layer-joined Mo support substrate, joint strength between the support substrate and the conductive layer was good, that is, not lower than 5 MPa (GaN conductive layer failure at a joint interface).

2. Formation of Active Layer

Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined Mo support substrate (conductive-layer-joined metal-made support substrate 12).

3. Formation of Electrode

Then, as in Example A1, electrode 40 (the Schottky electrode having a diameter of 200 μm) was formed on n-GaN layer 32, to thereby obtain an SBD serving as the power device.

4. Characteristics of Power Device

Regarding the obtained SBD, on-resistance was as low as 1.08 mΩ·cm², forward voltage Vf at current density of 500 A/cm² was as low as 1.26 V, and a reverse blocking voltage at leakage current density of 1×10⁻³ A/cm² was as high as 301 V. Table 2 summarizes the results.

### Comparative Example RA1

1. Preparation of Conductive Free-Standing Group III Nitride Substrate

Referring first to FIGS. 4 and 10, the conductive free-standing GaN substrate (conductive free-standing group III nitride substrate 120) grown with the HVPE method, cleaned, subjected to mirror polishing of both main surfaces, doped with oxygen, and having a diameter of 2 inches (50.8 mm) and a thickness of 350 μm was prepared as in Example A1 (the step of preparing a conductive free-standing group III nitride substrate S11). This conductive free-standing GaN substrate had a main surface having an off angle of 0.5° with respect to the (0001) plane and carrier concentration of approximately 5×10¹⁸ cm⁻³.

2. Formation of Active Layer

Referring next to FIGS. 4 and 10, group III nitride active layer 130 (an n⁺-GaN layer 131 having carrier concentration of 1×10¹⁸ cm⁻³ and a thickness of 0.5 μm and an n-GaN layer 132 having carrier concentration of 7×10¹⁵ cm⁻³ and a thickness of 5 μm) was grown on one main surface 120m of the conductive free-standing GaN substrate (conductive free-standing group III nitride substrate 120) as in Example A1 (the step of forming an active layer S12).

3. Formation of Electrode

Referring next to FIGS. 4 and 10, an ohmic electrode was formed as substrate-side electrode 150 on the other main surface 120n of the conductive free-standing GaN substrate (conductive free-standing group III nitride substrate 120) (the step of forming a substrate-side electrode S33) and a Schottky electrode was formed as an active-layer-side electrode 140 on n-GaN layer 32 (the step of forming an active-layer-side electrode S34), as follows.

Initially, the back main surface (N atomic plane) (main surface 120n) of the conductive free-standing GaN substrate was subjected to organic cleaning. Specifically, ultrasonic cleaning with acetone for 5 minutes, ultrasonic cleaning with IPA for 5 minutes, and ultrasonic cleaning with pure water for 5 minutes were successively performed, followed by drying with nitrogen gas blowing. Then, a layer composed of Ti/Al/Ti/Au having thicknesses of 20 nm/100 nm/20 nm/300 nm respectively was formed with the EB vapor deposition method on the entire back main surface (N atomic plane) of the conductive free-standing GaN substrate, that was in turn subjected to heat treatment for 1 minute at 600° C. in the N₂ gas, to thereby obtain the ohmic electrode (substrate-side electrode 150). Then, as in Example A1, a Schottky electrode having a diameter of 200 μm (active-layer-side electrode 140) was formed on n-GaN layer 32, to thereby obtain an SBD serving as a power device. Thus, in Comparative Example RA1, not only the Schottky electrode (active-layer-side electrode 140) but also the ohmic electrode (substrate-side electrode 150) had to be formed.

4. Characteristics of Power Device

Regarding the obtained SBD, on-resistance was as high as 1.38 mΩ·cm², forward voltage Vf at current density of 500 A/cm² was as high as 1.42 V, a reverse blocking voltage at leakage current density of 1×10⁻³ A/cm² was as high as 342 V. Table 2 summarizes the results.

### Example A4

A GaN-conductive-layer-joined W/Mo support substrate (conductive-layer-joined metal-made support substrate 12) was prepared as in Example A2 except that a W/Mo support substrate in which a W layer (metal layer 10a) having a thickness of 0.2 μm was formed on one main surface of a Mo underlying substrate (metal underlying substrate 10b) having a thickness of 500 μm was employed as metal-made support substrate 10. Regarding the obtained GaN-conductive-layer-joined W/Mo support substrate, joint strength between the support substrate and the conductive layer was excellent, that is, not lower than 10 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined W/Mo support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as a power device. Regarding the obtained SBD, on-resistance was as low as 1.10 mΩ·cm², forward voltage Vf at current density of 500 A/cm² was as low as 1.27 V, a reverse blocking voltage at leakage current density of 1×10⁻³ A/cm² was as high as 320 V. Table 2 summarizes the results.

### Example A5

A GaN-conductive-layer-joined Ti/Mo support substrate (conductive-layer-joined metal-made support substrate 12) was prepared as in Example A2 except that a Ti/Mo support substrate in which a Ti layer (metal layer 10a) having a thickness of 0.2 μm was formed on one main surface of a Mo underlying substrate (metal underlying substrate 10b) having a thickness of 500 μm was employed as metal-made support substrate 10. Regarding the obtained GaN-conductive-layer-joined Ti/Mo support substrate, joint strength between the support substrate and the conductive layer was excellent, that is, not lower than 10 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined Ti/Mo support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as a power device. Regarding the obtained SBD, on-resistance was as low as 1.11 mΩ·cm², forward voltage Vf at current density of 500 A/cm² was as low as 1.28 V, a reverse blocking voltage at leakage current density of 1×10⁻³ A/cm² was as high as 325 V. Table 2 summarizes the results.

### Example A6

A GaN-conductive-layer-joined Ta/Mo support substrate (conductive-layer-joined metal-made support substrate 12) was prepared as in Example A2 except that a Ta/Mo support substrate in which a Ta layer (metal layer 10a) having a thickness of 0.2 μm was formed on one main surface of a Mo underlying substrate (metal underlying substrate 10b) having a thickness of 500 μm was employed as metal-made support substrate 10. Regarding the obtained GaN-conductive-layer-joined Ta/Mo support substrate, joint strength between the support substrate and the conductive layer was excellent, that is, not lower than 10 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined Ta/Mo support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as a power device. Regarding the obtained SBD, on-resistance was as low as 1.12 mΩ·cm², forward voltage Vf at current density of 500 A/cm² was as low as 1.30 V, and a reverse blocking voltage at leakage current density of 1×10⁻³ A/cm² was as high as 323 V. Table 2 summarizes the results.

### Example A7

A GaN-conductive-layer-joined W support substrate (conductive-layer-joined metal-made support substrate 12) was prepared as in Example A2 except that a W support substrate having a thickness of 500 μm was employed as metal-made support substrate 10. Regarding the obtained GaN-conductive-layer-joined W support substrate, joint strength between the support substrate and the conductive layer was good, that is, not lower than 5 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined W support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as a power device. Regarding the obtained SBD, on-resistance was as low as 1.13 mΩ·cm², forward voltage Vf at current density of 500 A/cm² was as low as 1.30 V, and a reverse blocking voltage at leakage current density of 1×10⁻³ A/cm² was as high as 330 V. Table 2 summarizes the results.

### Example A8

A GaN-conductive-layer-joined Ta support substrate (conductive-layer-joined metal-made support substrate 12) was prepared as in Example A2 except that a Ta support substrate having a thickness of 500 μm was employed as metal-made support substrate 10. Regarding the obtained GaN-conductive-layer-joined Ta support substrate, joint strength between the support substrate and the conductive layer was good, that is, not lower than 5 MPa (GaN conductive layer failure at a joint interface). Then, as in Example A1, group III nitride active layer 30 (n⁺-GaN layer 31 having carrier concentration of 1×10¹⁸ cm⁻³ and a thickness of 0.5 μm and n-GaN layer 32 having carrier concentration of 7×10¹⁵ cm⁻³ and a thickness of 5 μm) was grown on the front main surface (Ga atomic plane) (main surface 20m) of the GaN-conductive-layer-joined Ta support substrate (conductive-layer-joined metal-made support substrate 12). Then, as in Example A1, electrode 40 (the Schottky electrode having a diameter of 200 μm) was formed on n-GaN layer 32, to thereby obtain an SBD serving as a power device. Regarding the obtained SBD, on-resistance was as low as 1.10 mΩ·cm², forward voltage Vf at current density of 500 A/cm² was as low as 1.28 V, and a reverse blocking voltage at leakage current density of 1×10⁻³ A/cm² was as high as 320 V. Table 2 summarizes the results.

TABLE 2

| | | Comparative | Example | Example | Example | Example | Example | Example | Example | Example |
|---|---|---|---|---|---|---|---|---|---|---|
| | | Example RA1 | A1 | A2 | A3 | A4 | A5 | A6 | A7 | A8 |
| Support | Metal | Conductive | Mo | Mo | Mo | Mo | Mo | Mo | W | Ta |
| Substrate | Underlying | Free-Standing | | | | | | | | |
| | Substrate | GaN Substrate | | | | | | | | |
| | Metal | | | | | W | Ti | Ta | | |
| | Layer | | | | | | | | | |

| | | | | | | | | | |
|---|---|---|---|---|---|---|---|---|---|
| Joint Strength Between | — | Good | Good | Good | Excellent | Excellent | Excellent | Good | Good |
| Support Substrate and | | | | | | | | | |
| Conductive Layer | | | | | | | | | |
| Thickness of Conductive | 350 | 100 | 30 | 0.3 | 30 | 30 | 30 | 30 | 30 |
| Layer (μm) | | | | | | | | | |
| Device Type | SBD | SBD | SBD | SBD | SBD | SBD | SBD | SBD | SBD |
| On-Resistance | 1.38 | 1.18 | 1.11 | 1.08 | 1.10 | 1.11 | 1.12 | 1.13 | 1.10 |
| (mΩ · cm²) | | | | | | | | | |
| Forward Voltage Vf (V) | 1.42 | 1.33 | 1.28 | 1.26 | 1.27 | 1.28 | 1.30 | 1.30 | 1.28 |
| Reverse Blocking | 342 | 354 | 330 | 301 | 320 | 325 | 323 | 330 | 320 |
| voltage (V) | | | | | | | | | |

Referring to Table 2, in the SBD, by employing as the substrate, the metal-made support substrate instead of the conventional and typical conductive free-standing GaN substrate, the on-resistance was lowered while maintaining a high reverse blocking voltage, and consequently forward voltage Vf could be lowered (Comparative Example RA1 and Examples A1 to A8). In addition, as the GaN conductive layer has a smaller thickness, the on-resistance and forward voltage Vf were lowered (Examples A1 to A3). Moreover, an example in which a metal/metal support substrate in which a metal layer was formed on one main surface of the metal underlying substrate was employed as the metal-made support substrate was excellent in joint strength between the support substrate and the conductive layer (Examples A4 to A6).

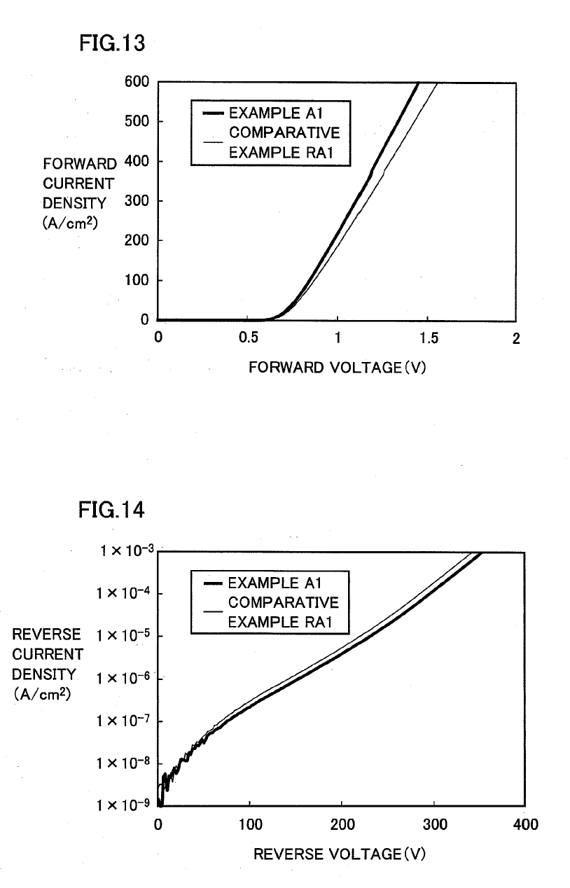

Here, FIG. 13 shows forward current-voltage characteristics of the SBDs fabricated in Example A1 and Comparative Example RA1 and FIG. 14 shows reverse current-voltage characteristics thereof. Referring to FIG. 13, in Example A1, an SBD lower in on-resistance by approximately 0.2 Ω·cm² and lower in forward voltage Vf at current density of 500 A/cm² by approximately 1 V than in Comparative Example RA1 was obtained. This may be because the SBD in Example A1 had the GaN conductive layer (substrate) smaller in thickness than the SBD in Comparative Example RA1 and had the Mo support substrate significantly low in specific resistance. Meanwhile, Example A1 was equivalent to Comparative Example RA1 in reverse blocking voltage at a leakage current density of 1×10⁻³ A/cm².

### Example B

An example where a PND was manufactured as a power device will be described as an Example B. Example B includes an Example B1 and a Comparative Example RB1 as follows.

### Example B1

1. Preparation of Conductive-Layer-Joined Metal-Made Support Substrate

Referring to FIGS. 5 and 9, a GaN-conductive-layer-joined Mo support substrate (conductive-layer-joined metal-made support substrate 12) was prepared as in Example A2 (the step of preparing a conductive-layer-joined metal-made support substrate S1). Regarding such a GaN-conductive-layer-joined Mo support substrate, joint strength between the support substrate and the conductive layer was good, that is, not lower than 5 MPa (GaN conductive layer failure at a joint interface).

2. Formation of Active Layer

Referring next to FIGS. 5 and 9, n⁺-GaN layer 31 having a thickness of 0.5 μm (carrier concentration: 1×10¹⁸ cm⁻³), n-GaN layer 32 having a thickness of 7 μm (carrier concentration: 3×10¹⁶ cm⁻³), p-GaN layer 33 having a thickness of 0.5 μm (Mg concentration: 7×10¹⁷ cm⁻³), and p⁺-GaN layer 34 having a thickness of 75 nm and serving as a contact layer (Mg concentration: 1×10¹⁹ cm⁻³) were grown with the MOCVD method as group III nitride active layer 30 on one main surface 20m of the GaN-conductive-layer-joined Mo support substrate (conductive-layer-joined metal-made support substrate 12) (the step of forming an active layer S2). Here, Mg concentration was measured with SIMS (secondary ion mass spectrometry). In growing the active layer above, a growth temperature was set to 1050° C., a growth pressure was set to 200 Torr (26.7 kPa), TMG (trimethylgallium) and the NH₃ (ammonia) gas were employed as a source gas, an SiH₄ (silane) gas and a CP₂Mg (cyclopentadienyl magnesium) gas were employed as a dopant gas, and an H₂ gas was employed as a carrier gas.

3. Formation of Electrode

Referring next to FIGS. 5 and 9, a resist mask (not shown) patterned by photolithography was formed on p⁺-GaN layer 34, and a part of p⁺-GaN layer 34 and p-GaN layer 33 was subjected to RIE (reactive ion etching), to thereby form a mesa shape. Then, the surface of p⁺-GaN layer 34 was subjected to organic cleaning. Specifically, ultrasonic cleaning with acetone for 5 minutes, ultrasonic cleaning with IPA for 5 minutes, and ultrasonic cleaning with pure water for 5 minutes were successively performed, followed by drying with nitrogen gas blowing. Then, a p-ohmic electrode was formed as electrode 40 on p⁺-GaN layer 34, with photolithography, pre-treatment of the surface with a 10 mass % hydrochloric acid aqueous solution, and formation of Ni/Au (an Ni layer having a thickness of 50 nm and an Au layer having a thickness of 100 nm) by resistance heating vapor deposition and lift-off followed by alloying at 700° C. in the N₂ gas (the step of forming an electrode S3). Regarding the size of an electrode portion and a portion in the vicinity thereof, the p-ohmic electrode had a diameter of 50 μm, and p⁺-GaN layer 34 and p-GaN layer 33 forming a mesa-shaped portion had a diameter of 60 μm. A PND serving as a power device was thus obtained.

4. Characteristics of Power Device

Regarding the obtained PND, on-resistance at current density of 500 A/cm² was as low as 0.60 mΩ·cm², forward voltage Vf at current density of 500 A/cm² was as low as 4.10 V, and a reverse blocking voltage at leakage current density of 1×10⁻³ A/cm² was 830 V. Table 3 summarizes the results.

### Comparative Example RB1

1. Preparation of Conductive Free-Standing Group III Nitride Substrate

Referring first to FIGS. 6 and 10, a conductive free-standing GaN substrate (conductive free-standing group III nitride substrate 120) as in Comparative Example RA1 was prepared (the step of preparing a conductive free-standing group III nitride substrate S11).

2. Formation of Active Layer

Referring next to FIGS. 6 and 10, group III nitride active layer 130 (n⁺-GaN layer 131 having a thickness of 0.5 μm (carrier concentration: 1×10¹⁸ cm⁻³), n-GaN layer 132 having a thickness of 7 μm (carrier concentration: 3×10¹⁶ cm⁻³), a p-GaN layer 133 having a thickness of 0.5 μm (Mg concentration: 7×10¹⁷ cm³), and a p⁺-GaN layer 134 having a thickness of 75 nm (Mg concentration: 1×10¹⁹ cm⁻³)) was grown as in Example B1 on one main surface 120m of the conductive free-standing GaN substrate (conductive free-standing group III nitride substrate 120) (the step of forming an active layer S12).

3. Formation of Electrode

Referring next to FIGS. 6 and 10, as in Example B1, a p-ohmic electrode was formed as active-layer-side electrode 140 on p⁺-GaN layer 34 (the step of forming an active-layer-side electrode S43). Then, a layer composed of Ti/Al/Ti/Au having thicknesses of 20 nm/100 nm/20 nm/300 nm respectively was formed with the EB vapor deposition method on the entire back main surface (N atomic plane) of the conductive free-standing GaN substrate, that was in turn subjected to heat treatment for 1 minute at 600° C. in the N₂ gas, to thereby form an n-ohmic electrode as substrate-side electrode 150 (the step of forming a substrate-side electrode S44). A PND serving as a power device was thus obtained. Thus, in Comparative Example RB1, not only the p-ohmic electrode (active-layer-side electrode 140) but also the n-ohmic electrode (substrate-side electrode 150) had to be formed.

4. Characteristics of Power Device

Regarding the obtained PND, on-resistance at current density of 500 A/cm² was as high as 0.87 mΩ·cm², forward voltage Vf at current density of 500 A/cm² was as high as 4.25 V, and a reverse blocking voltage at leakage current density of 1×10⁻³ A/cm² was 850 V. Table 3 summarizes the results.

TABLE 3

| | Comparative Example RB1 | Example B1 |
|---|---|---|
| Support Substrate | Conductive Free-Standing | Mo |
| | GaN Substrate | |
| Joint Strength Between Support | | |
| Substrate and Conductive Layer | — | Good |
| Thickness of Conductive Layer | 350 | 30 |
| (μm) | | |
| Device Type | PND | PND |
| On-Resistance (mΩ · cm²) | 0.87 | 0.60 |
| Forward Voltage Vf (V) | 4.25 | 4.10 |
| Reverse Blocking voltage (V) | 850 | 830 |

Referring to Table 3, in the PND as well, by employing as the substrate, the metal-made support substrate instead of the conventional and typical conductive free-standing GaN substrate, the on-resistance and forward voltage Vf could be lowered while maintaining a high reverse blocking voltage (Comparative Example RB1 and Example B1).

### Example C

An example where a MIS transistor was manufactured as a power device will be described as an Example C. Example C includes an Example C1 and a Comparative Example RC1 as follows.

### Example C1

1. Preparation of Conductive-Layer-Joined Metal-Made Support Substrate

Referring to FIGS. 7 and 9, a GaN-conductive-layer-joined Mo support substrate (conductive-layer-joined metal-made support substrate 12) was prepared as in Example A2 (the step of preparing a conductive-layer-joined metal-made support substrate S1).

2. Formation of Active Layer

Referring next to FIGS. 7 and 9, n⁺-GaN layer 31 having a thickness of 0.5 μm (carrier concentration: 1×10¹⁸ cm⁻³), n-GaN layer 32 having a thickness of 7 μm (carrier concentration: 3×10¹⁶ cm⁻³), p-GaN layer 33 having a thickness of 0.5 μm (Mg concentration: 7×10¹⁷ cm⁻³), and n⁺-GaN layer 36 having a thickness of 0.5 μm (carrier concentration: 1×10¹⁸ cm⁻³) were grown with the MOCVD method as group III nitride active layer 30 on one main surface 20m of the GaN-conductive-layer-joined Mo support substrate (conductive-layer-joined metal-made support substrate 12) (the step of forming an active layer S2). In growing the active layer above, a growth temperature was set to 1050° C., a growth pressure was set to 200 Torr (26.7 kPa), TMG (trimethylgallium) and the NH₃ (ammonia) gas were employed as a source gas, an SiH₄ (silane) gas and a CP₂Mg (cyclopentadienyl magnesium) gas were employed as a dopant gas, and an H₂ gas was employed as a carrier gas.

3. Formation of Electrode

Referring next to FIGS. 7 and 9, the surface of n⁺-GaN layer 36 was subjected to organic cleaning. Specifically, ultrasonic cleaning with acetone for 5 minutes, ultrasonic cleaning with IPA for 5 minutes, and ultrasonic cleaning with pure water for 5 minutes were successively performed, followed by drying with nitrogen gas blowing. Then, source electrode 41 representing one of electrodes 40 was formed on a part of n⁺-GaN layer 36, with photolithography, pre-treatment of the surface with a 10 mass % hydrochloric acid aqueous solution, and formation of Ti/Al/Ti/Au having thicknesses of 20 nm/100 nm/20 nm/300 nm respectively with EB vapor deposition and lift-off, followed by heat treatment for 1 minute at 600° C. in the N₂ gas. Then, n⁺-GaN layer 36, p-GaN layer 33 and n-GaN layer 32 were etched by RIE to form a mesa shape, in a part of group III nitride active layer 30 where source electrode 41 is not formed. An SiO₂ layer having a thickness of 100 nm was formed as insulating layer 50 on that etched portion (a mesa slope) with a p-CVD (plasma chemical vapor deposition) method. Then, by performing heat treatment for 30 minutes at 1000° C. in the N₂ gas, defects at the interface between the SiO₂ layer and the GaN layer were reduced. Then, a gate electrode as one of electrodes 40 was formed on the SiO₂ layer (insulating layer 50), by resistance heating vapor deposition and lift-off of Ni/Au (an Ni layer having a thickness of 50 nm/an Au layer having a thickness of 100 nm) (the step of forming an electrode S3). A MIS transistor serving as a power device was thus obtained.

### Comparative Example RC1

1. Preparation of Conductive Free-Standing Group III Nitride Substrate

Referring first to FIGS. 8 and 10, a conductive free-standing GaN substrate (conductive free-standing group III nitride substrate 120) as in Comparative Example RA1 was prepared (the step of preparing a conductive free-standing group III nitride substrate S11).

2. Formation of Active Layer

Referring next to FIGS. 8 and 10, n⁺-GaN layer 131 having a thickness of 0.5 μm (carrier concentration: 1×10¹⁸ cm⁻³), n-GaN layer 132 having a thickness of 7 μm (carrier concentration: 3×10¹⁶ cm³), p-GaN layer 133 having a thickness of 0.5 μm (Mg concentration: 7×10¹⁷ cm⁻³), and an n⁺-GaN layer 136 having a thickness of 0.5 μm (carrier concentration: 1×10¹⁸ cm⁻³) were grown as group III nitride active layer 130 with the MOCVD method as in Example C1 on one main surface 120m of the conductive free-standing GaN substrate (conductive free-standing group III nitride substrate 120) (the step of forming an active layer S12).

3. Formation of Electrode

Referring next to FIGS. 8 and 10, as in Example C1, a source electrode 141 and a gate electrode 142 were formed as active-layer-side electrode 140 on n⁺-GaN layer 136 and on the SiO₂ layer (insulating layer 50) formed in a mesa shape, respectively (the step of forming an active-layer-side electrode S43). Then, a layer composed of Ti/Al/Ti/Au having thicknesses of 20 nm/100 nm/20 nm/300 nm respectively was formed with the EB vapor deposition method on the entire back main surface (N atomic plane) of the conductive free-standing GaN substrate, to thereby form a drain electrode as substrate-side electrode 150 (the step of forming a substrate-side electrode S44). A MIS transistor serving as a power device was thus obtained. Thus, in Comparative Example RC1, not only source electrode 141 and gate electrode 142 (active-layer-side electrode 140) but also the drain electrode (substrate-side electrode 150) had to be formed.

Comparing Example C1 and Comparative Example RC1 with each other with regard to characteristics of the obtained MIS transistor, on-resistance at a gate voltage of 10 V was lower in Example C1 by approximately 0.2 mΩ·cm² than in Comparative Example RC1. Thus, the on-resistance could be lowered by employing the metal-made support substrate instead of the conductive free-standing GaN substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A power device, comprising:
a metal-made support substrate; and
a group III nitride conductive layer, a group III nitride active layer, and an electrode successively formed on one main surface side of said metal-made support substrate.

2. The power device according to claim 1, wherein
said metal-made support substrate has a difference between a coefficient of thermal expansion of said metal-made support substrate and a coefficient of thermal expansion of said group III nitride conductive layer not greater than 4.5×10⁻⁶ K⁻¹ and a melting point higher than 1100° C., and it is chemically stable against an NH₃ gas and an H₂ gas in an atmosphere not higher than 1100° C.

3. The power device according to claim 2, wherein
said metal-made support substrate contains any element selected from the group consisting of Mo, W and Ta.

4. The power device according to claim 1, wherein
said metal-made support substrate includes a metal underlying substrate and at least one metal layer formed on one main surface of said metal underlying substrate.

5. The power device according to claim 4, wherein
said metal underlying substrate contains any element selected from the group consisting of Mo, W and Ta, and
said metal layer contains any element selected from the group consisting of W, Ti and Ta.

6. The power device according to claim 1, wherein
said group III nitride conductive layer has a thickness not smaller than 0.05 μm and not greater than 100 μm.

7. A method for manufacturing a power device, comprising the steps of:
preparing a conductive-layer-joined metal-made support substrate in which a group III nitride conductive layer is joined to a metal-made support substrate;
forming a group III nitride active layer on said group III nitride conductive layer; and
forming an electrode on said group III nitride active layer.

8. The method for manufacturing a power device according to claim 7, wherein
a temperature at which said group III nitride active layer is formed is not lower than 700° C.
